(19) United States
(12) Patent Application Publication
(10) Pub. No.: US 2002/0175620 A1
(43) Pub. Date: Nov. 28, 2002

(54) Organic EL device and display panel incorporating the organic EL device

(76) Inventors: Osamu Yokoyama, Shiojiri-shi (JP); Masahiro Uchida, Fujimi-cho (JP)

Correspondence Address: OLIFF & BERRIDGE, PLC, P.O. BOX 19928, ALEXANDRIA, VA, 22320, US

(21) Appl. No.: 09/825,848

(22) Filed: Apr. 5, 2001

(30) Foreign Application Priority Data
Apr. 6, 2000 (JP) 2000-104967

(51) Int. Cl. H05B 33/00

(52) U.S. Cl. 313/505

(57) ABSTRACT

The present invention provides an organic EL display device in which a transparent electrode pattern on the substrate is barely visible when no luminescence occurs in the organic EL elements. A transparent anode layer deposited on a transparent substrate is formed in a pattern which corresponds to a light emitting pattern. In the same plane with the anode layer within the display area, a dummy pattern is provided, such that it is electrically isolated from the anode layer. The dummy pattern is made of the same material and is formed with the same thickness as the anode layer. Thus, an interface between the transparent substrate, and a layer made of the anode layer material (the anode layer and the dummy pattern) is formed over the entire display area. When the organic EL elements are not light emitting, light reflection on the interface occurs uniformly over the entire display area.

### BACKGROUND OF THE INVENTION

1. Field of Invention

The present invention relates to an organic EL display provided with organic EL (electroluminescence) elements as its display elements, and an organic EL device and display panel containing a light source that includes organic EL elements (an organic EL panel, a liquid crystal panel, etc. provided with an organic light emitting layer, a liquid crystal layer, etc. as the display elements layer).

2. Description of Related Art

An organic EL element is a self-luminescent element (or light emitting element) having a structure where an organic light emitting layer is placed between a cathode and an anode. As an example of the structure of the organic EL element, a thin film layered structure can be provided where a thin film (an anode layer) made of a transparent, conductive material, an organic light emitting layer made of one or more layers of organic thin films, and a metallic thin film (a cathode layer) are sequentially deposited onto a transparent substrate. In accordance with the organic EL element of this structure, even with a low DC voltage of about 5 V, it is possible to achieve a luminescence that is bright enough to be visible.

FIGS. 4(a) and 4(b) show a conventional example of an organic EL display provided with such organic EL elements as its display elements. FIG. 4(a) is a plan view of the display panel forming this display, and FIG. 4(b) is a cross-sectional view taken along plane B-B′ of FIG. 4(a).

As shown in FIG. 4(b), this display panel includes a transparent substrate 10, a transparent anode layer 11, an organic light emitting layer 15 equipped with a hole transporting layer etc., and a cathode layer 16 made of a metallic thin film. In FIG. 4(a), the organic light emitting layer 15 and the cathode 16 are omitted.

The display panel is a display that displays digital figures and includes seven elements (light emitting pattern) that include a digital figure and made of organic EL elements. As shown in FIG. 4(a), the anode layer 11 is formed on the substrate 10 in a pattern corresponding to the seven elements which include the light emitting pattern. Each element in the pattern of this anode layer 11 includes an element section 11a having the same shape as the element to which is connected wiring 11b. The pattern is formed by photolithography and etching after an ITO thin film has been formed on the substrate 10.

In an area that extends slightly outside of the display area 12 on the substrate 10 where the anode layer 11 is formed, the organic light emitting layer 15 is formed. The cathode layer 16 is formed inside the same area as the display area 12 on the organic light emitting layer 15. The area outside of the display area 12 is covered with the display device housing.

The display panel is used by connecting each terminal (the portion of each wiring 11b outside of the display area 12) of the anode layer 11 and the terminal of the cathode layer 16 to the corresponding terminal of the driving circuit. Then, by operating the driving circuit, electric conduction is caused between the anode terminal of the part to be made light emitting among the seven elements and the cathode terminal, and luminescence occurs in the organic light emitting layer 15 of the electrified part, and one of digital figures “0”˜“9” is displayed.

Therefore, as shown in FIG. 4(b), through the transparent substrate 10, radiated light can be seen from the organic light emitting layer 15, between the electrified element section 11a of the anode layer 11 and the cathode layer 16.

Normally, in the organic EL display panel of the conventional structure described above, a substrate made of soda glass, whose refractive index is about 1.5, is used as the transparent substrate 10, and ITO (Indium Tin Oxide; Indium oxide doped with tin oxide), whose refractive index is about 2.0, is used as the transparent anode layer 11. If, in this way, the difference in the refractive index is large between the substrate 10 and the anode layer 11, reflectivity on the interface between the substrate 10 and the anode layer 11 becomes high, and a case can arise where the pattern of the anode layer 11 becomes visible, even when no luminescence is occurring in the organic light emitting layer.

### SUMMARY OF THE INVENTION

The present invention addresses the above problems of the conventional art technology, and its object is to provide a transparent electrode pattern that is barely visible when the corresponding electrode pattern is not electrified in a display panel, such as an organic EL display panel.

In order to solve the aforementioned problems, the present invention provides an organic EL device where a layered structure, having an organic light emitting layer between the electrode layers, is formed on a substrate, a first electrode layer, which is one of electrode layers, is transparent, and the first electrode layer is formed in a pattern corresponding to the light emitting pattern. The organic EL device has a dummy pattern placed in the same plane as the first electrode layer so that it is electrically isolated from the first electrode layer.

The present invention provides an organic EL device where a layered structure having an organic light emitting layer between the electrode layers is formed on a substrate, each electrode layer is formed in a pattern where part of the electrode layers overlap each other, and the overlapping part of the two electrode layers includes light emitting sections made of organic EL elements. The first electrode layer, which is one of the electrode layers, is transparent, and has a dummy pattern that has one of the following structures:

\mathring{1} dummy pattern placed in the same plane as the first electrode layer so that it is electrically isolated from the first electrode layer; or

\mathring{2} A dummy pattern placed in the same plane as the second electrode layer, which is the other electrode layer, so that it is electrically isolated from the second electrode layer.

The dummy pattern can be formed of the same material as the first electrode layer.

The dummy pattern, placed in the same plane as the first electrode layer, can be formed of the same material as the first electrode layer, and the dummy pattern placed in the same plane as the second electrode layer can be formed of the same material as the second electrode layer.

The dummy pattern can be formed within the light emitting area of the organic light emitting layer.

The substrate can be transparent, and the first electrode layer can be an electrode layer formed on the substrate-side face of the organic light emitting layer.

The substrate can be made of soda glass, and the first electrode layer can be made of ITO (Indium Tin Oxide).

The second electrode layer, formed on the opposite face of the substrate of the organic light emitting layer, can be transparent.

The present invention also provides a display panel where a layered structure, having a display element layer between the electrode layers, is formed on a substrate, a first electrode layer, which is one of the electrode layers, is transparent. The first electrode layer is formed in a pattern corresponding to the light emitting pattern, and the pattern is displayed by applying a voltage between the electrode layers. A dummy pattern is provided within the display area. The dummy pattern is made of the same material as the first electrode layer, and is placed in the same plane as the first electrode layer so that it is electrically isolated from the first electrode layer.

The present invention also provides a display panel where a layered structure, having a display element layer between electrode layers, is formed on a substrate, the formation of each electrode layer in a pattern where part of the electrode layers overlap each other. The overlapping part of the electrode layers includes a display element section. The pattern is displayed by applying a voltage between the electrode layers, and the display panel, in which the first electrode layer, which is one of the electrode layers, is transparent, and has a dummy pattern that has one of the following structures:

\mathring{3} A dummy pattern, which is made of the same material as the first electrode layer, and is placed in the same plane as the first electrode layer, so that it is electrically isolated from the first electrode layer; or

\mathring{4} A dummy pattern, which is made of the same material as the second electrode layer, and is placed in the same plane as the second electrode layer, which is the other electrode layer, so that it is electrically isolated from the second electrode layer.

The substrate can be transparent, and the first electrode layer can be an electrode layer formed on the substrate-side face of the display element layer.

The substrate can be made of soda glass, and the first electrode layer can be made of ITO (Indium Tin Oxide).

### BRIEF DESCRIPTION OF THE DRAWINGS

FIGS. 1(a) and 1(b) show the structure of an organic EL display panel in accordance with a first embodiment of the present invention, where FIG. 1(a) is a plan view of this display panel, and FIG. 1(b) is a cross-sectional view taken along plane A-A′ of FIG. 1(a);

FIG. 2 shows the structure of an organic EL display panel in accordance with a second embodiment of the present invention, which corresponds to a view taken along plane A-A′ of FIG. 1(a);

FIGS. 3(a)-3(c) show the structure of an organic EL display panel in accordance with a third embodiment of the present invention, where FIG. 3(a) is a plan view of the display panel, FIG. 3(b) is a cross-sectional view taken along plane B-B′ of FIG. 3(a), and FIG. 3(c) is a cross-sectional view taken along plane C-C′ of FIG. 3(a);

FIGS. 4(a) and 4(b) show the structure of a conventional example of an organic EL display panel, where FIG. 4(a) is a plan view of this display panel, and FIG. 4(b) is a cross-sectional view taken along plane B-B′ of FIG. 4(a).

### DETAILED DESCRIPTION OF PREFERRED EMBODIMENTS

Embodiments of the present invention are explained below.

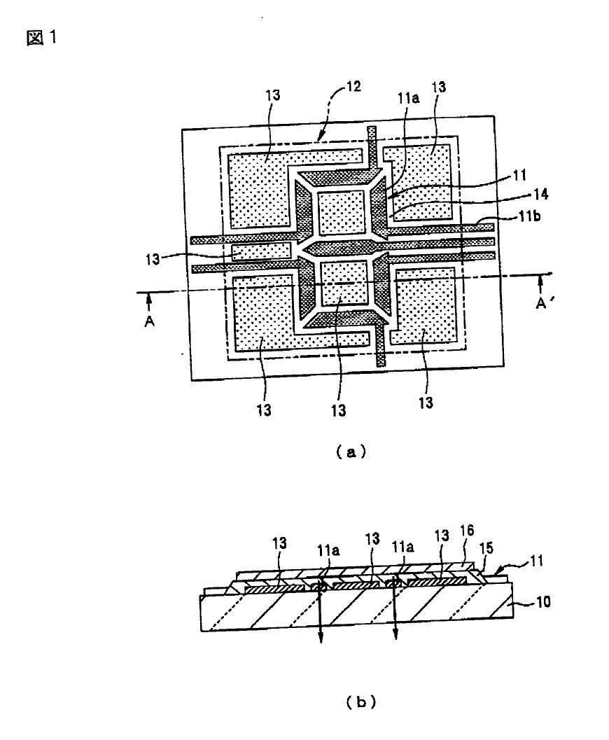

The structure of an organic EL display panel in accordance with a first embodiment of the present invention is explained hereafter, with reference to FIGS. 1(a) and 1(b). FIG. 1(a) is a plan view of this display panel, and FIG. 1(b) is a cross-sectional view taken along plane A-A′ of FIG. 1(a).

As shown in FIG. 1(b), the display panel includes a transparent substrate 10, a transparent anode layer (first electrode layer) 11, a dummy pattern 13, an organic light emitting layer 15 provided with a hole transporting layer etc., and a cathode layer 16 made of a metallic thin film. In FIG. 1(a), the organic light emitting layer 15 and the cathode layer 16 are omitted.

The display panel is a display that displays digital figures, where seven elements (light emitting pattern) that includes a digital figure are made of organic EL elements. As shown in FIG. 1(a), the anode layer 11 is formed on the substrate 10 in a pattern corresponding to the seven elements which includes the light emitting pattern. Each element of the pattern of the anode layer 11 includes an element section 11a, which has the same shape as the element, and a wiring 11b connected to it.

On the part within the display area other than the anode layer 11, the dummy pattern 13, that is made of the same material as the anode layer 11, is formed on the same plane as the anode layer 11. The dummy pattern 13 is formed with the same thickness as the anode layer 11. Also, the dummy pattern 13 is formed in a state isolated electrically from the anode layer 11 by providing a space 14 between the anode layer 11 and itself.

The space 14 between the pattern-shape anode layer 11 and the dummy pattern 13 is formed by forming a thin film, that is made of a material forming an anode layer 11, on the substrate 10, and then performing photolithography and etching to the thin film.

In the embodiment, a substrate made of soda glass, whose thickness is 0.7 mm and refractive index is about 1.5, is used as the substrate 10. As the material forming the anode layer 11, ITO, whose refractive index is 2.0, is used, where the thickness of the ITO thin film is made to be 150 nm, and the width of the space 14 is made to be a size that is not visible to the naked eye (10 μm for example).

The organic light emitting layer 15 is formed of a hole transporting layer made of N,N′-diphenyl-N,N′-dinaphthyl-1,1′-bisphenyl-4,4′diamine, and an electron transporting light emitting layer made of tris-(8-hydroxyquinoline) aluminum complex. The hole transporting layer and the electron transporting light emitting layer are formed with a thickness of 50 μm, making the thickness 100 nm as the organic light emitting layer 15. The cathode layer 16 is made of an alloy thin film with a composition of magnesium:silver=10:1, and the thickness is made to be 200 nm.

The display panel is used by connecting each terminal of the cathode layer 11 (a portion of each wiring 11b that lies outside the display area 12) and the terminal of the cathode layer 16 to each corresponding terminal of the driving circuit. Then, by operating the driving circuit, a voltage is applied between the anode terminal of the portion of the seven elements to be light emitting and the cathode terminal, thereby causing luminescence to occur in the electrified part of the organic light emitting layer 15, and a digital figure is displayed.

For example, electrification is performed by grounding the cathode layer 16 and applying a positive DC voltage (6 V for example) to a specified element section 11a of the anode layer 11. Thus, radiated light can be seen, through the transparent substrate 10, from the organic light emitting layer 15, which exists between the electrified element section 11a of the anode layer 11 and the cathode layer 16.

In the organic EL panel of the embodiment, because the difference in refractive index between the substrate 10 and the anode layer 11 or the dummy pattern 13 is large, reflectivity on the interface between the substrate 10 and the anode layer 11 or the dummy pattern 13 is high, and when no luminescence occurs in the organic light emitting layer 15, light reflected on the interfaces occur uniformly in the whole display area 12. Therefore, when no luminescence occurs in the organic light emitting layer 15, the pattern of the anode layer 11 becomes barely visible.

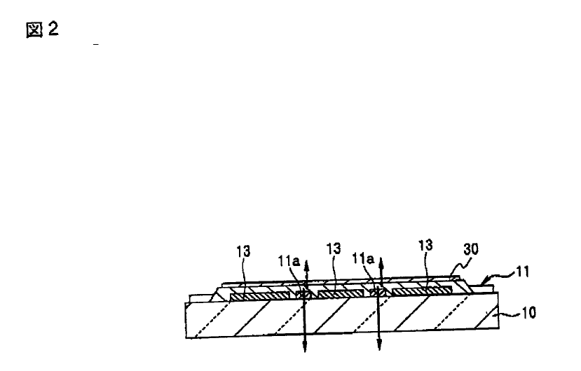

The structure of the organic EL display panel, which corresponds to the second embodiment of the present invention, is explained hereafter with reference to FIG. 2. The plan view of this organic EL display panel is the same as with FIG. 1(a), and FIG. 2 corresponds to a cross-sectional view taken along plane A-A′ of FIG. 1(a). This organic EL display panel is only different from the organic EL display panel of the first embodiment in the configuration of the cathode layer (second electrode layer) 30. The cathode layer 30 is a transparent thin film formed thin enough for light to be transmitted. Therefore, as shown in FIG. 2, light generated in the organic light emitting layer 15 is not only radiated from the transparent substrate 10 side to the outside, but also radiated from the cathode layer 30 side to the outside.

As the transparent cathode layer 30, \mathring{1} a thin film obtained by co-depositing magnesium (Mg) and silver (Ag), \mathring{2} a thin film obtained by co-depositing lithium (Li) and aluminum (Al), and \mathring{3} a thin film (whose total thickness is 140 Å or less for example) with a double-layer structure including the first cathode layer (light emitting layer side) made of a material with a small work function, and the second cathode layer with a larger work function than this layer, can be used, for example. Calcium (Ca) or magnesium (Mg) can be used as the raw material of the first cathode layer, and aluminum (Al), silver (Ag), and gold (Au) can be used as the raw material of the second cathode layer, for example.

By using the organic EL display panel placed on an analog display of a watch (dial face and hands), both analog display of time by the analog display, and display of digital figures by the organic EL display panel, can be provided on the same plane.

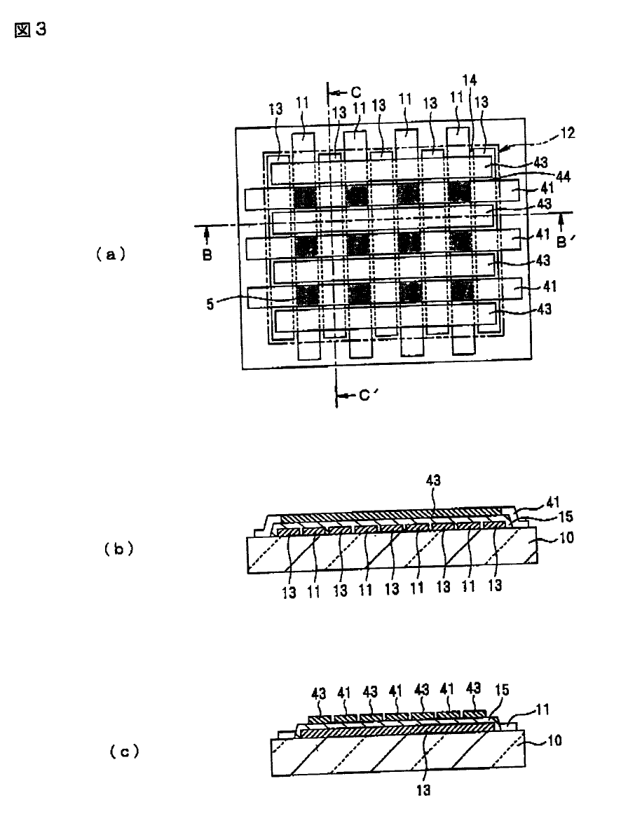

Referring to FIGS. 3(a)-3(c), the structure of an organic EL display panel in accordance with a third embodiment of the present invention is explained. FIG. 3(a) is a plan view of this display panel, FIG. 3(b) is a cross-sectional view taken along plane B-B′ of FIG. 3(a), and FIG. 3(c) is a cross-sectional view taken along plane C-C′ of FIG. 3(a).

The display panel includes, as shown in FIG. 3(b) and FIG. 3(c), a transparent substrate 10, a transparent anode layer (first electrode layer) 11, a dummy pattern 13 placed in the same plane as the anode layer 11, an organic light emitting layer 15 provided with a hole transporting layer etc., a cathode layer (second electrode layer) 41 made of a metallic thin film, and a dummy pattern 43 placed in the same plane as the cathode layer 41. In FIG. 3(a), the organic light emitting layer 15 is omitted.

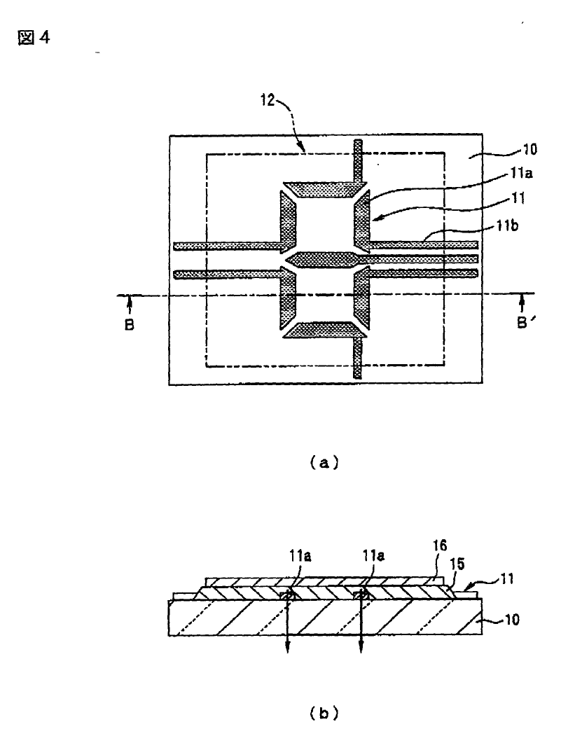

The display panel is a display panel for a passive matrix type organic EL display, where the anode layer 11 is formed immediately on the substrate 10 as a column electrode in a stripe pattern, as shown in FIG. 4(a). The cathode layer 41 is formed on the organic light emitting layer 15 as a row electrode in a stripe pattern. On the overlapping portion of both of the electrode layers 11 and 41, light emitting sections (pixels) 5, made of organic EL elements, are formed.

In the same plane as the anode layer 11, within the display area 12, between neighboring anode layers 11, a dummy pattern 13, made of the same material with the anode layer 11, is formed with the same thickness as the anode layer 11 in a stripe pattern.

In the same plane as the cathode layer 41 within the display area 12, between neighboring cathode layers 41, a dummy pattern 43, made of the same material with the cathode layer 41, is formed with the same thickness as the cathode layer 41 in a stripe pattern.

A space 14 is provided between the anode layer 11 and the dummy pattern 13 with a specified width, by which the dummy pattern 13 is formed in a state isolated electrically from the anode layer 11. Provided between the cathode layer 41 and the dummy pattern 43 is a space 44 with a specified width, by which the dummy pattern 13 is formed in a state isolated electrically from the anode layer 11.

The pattern-shape anode layer 11, the dummy pattern 13, and the space 14 between them are formed by forming a thin film made of a material forming the anode layer 11 on the substrate 10, and then performing photolithography and etching on the layer. The pattern-shape cathode layer 41, the dummy pattern 43, and the space 44 between them are formed by vapor coating with the cathode layer material through a mask covering the space 44 portion when forming a thin film made of a material forming the cathode layer 41 on the organic light emitting layer 15.

The configuration of other aspects than the aspects described above are the same as the configuration of the first embodiment.

Therefore, in the organic EL panel of this embodiment, because the difference in refractive index, between the substrate 10 and the anode layer 11 or the dummy pattern 13, is large, reflectivity on the interface, between the substrate 10 and the anode layer 11 or the dummy pattern 13, is high, and when no luminescence occurs in the organic light emitting layer 15, light reflection on the interfaces occurs uniformly in the entire display area 12. Also, when no luminescence occurs in the organic light emitting layer 15, light reflection on the interfaces, between the organic light emitting layer 15 and the cathode layer 41 or the dummy pattern 43, occurs uniformly in the entire display area 12. As a result, when no luminescence occurs in the organic light emitting layer 15, patterns of the anode layer 11 and the cathode layer 41 become barely visible.

In this instance, if only the difference in refractive index, between the substrate 10 and the anode layer 11, is large, and light reflection on the interface, between the organic light emitting layer 15 and the cathode layer 41, is small, it can also be so configured that only the dummy pattern 13 on the anode layer 11 is provided, and the dummy pattern 43 of the cathode layer 41 is not provided. Also, if only the light reflection on the interface, between the organic light emitting layer 15 and the cathode layer 41, is large, and the difference in refractive index, between the substrate 10 and the anode layer 11, is small, it can also be so configured that only the dummy pattern 43 of the cathode layer 41 is provided, and the dummy pattern 13 of the anode layer 11 is not provided.

Also, an organic EL display panel having a structure of this embodiment, where the cathode layer 41 is transparent, is also included in the present invention. Moreover, the present invention can be applied to a display panel for an active matrix type organic EL display.

Also, in the configuration of this embodiment, while a reflective substrate is transparent, and the first electrode layer is an electrode layer formed on the substrate-side face of the organic light emitting layer (display element layer), an organic EL device and display panel, having a configuration where the first electrode layer is formed on a face of the organic light emitting layer (display element layer) opposite from the substrate, is also included in the present invention. In this case, while a transparent layer that seals is formed on the first electrode layer opposite from the substrate and light radiated from the transparent layer to the outside is observed, by installing a dummy pattern on the first electrode layer, if the difference in the refractive index, between the transparent layer and the first electrode layer, is large, even when no luminescence occurs in the organic light emitting layer, the pattern of the first electrode can be made to be barely visible.

As explained above, in accordance with the organic EL device of the present invention, where no luminescence occurs in organic EL elements, the transparent electrode pattern can be barely visible.

Also, in accordance with the display panel of the present invention, when the transparent electrode pattern is not electrified, the electrode pattern can be barely visible.

The following are marked-up versions of the amended claims:

1. (Amended) An organic EL device having a layered structure, comprising: with
a substrate;
electrode layers formed above the substrate;
an organic light emitting layer provided between the electrode layers formed on a above the substrate, the electrode layers including a first electrode layer which is one of electrode layers having that has a transparent property, and the first electrode layer being formed in a pattern corresponding to a light emitting pattern; and the organic EL display having
a dummy pattern placed in the same plane as the first electrode layer, such that the dummy pattern is electrically isolated from the first electrode layer.

2. (Amended) An organic EL device having a layered structure comprising: with
a substrate;
electrode layers formed above the substrate;
an organic light emitting layer provided between the electrode layers formed on a above the substrate, each electrode layer being formed in such a pattern that part of the electrode layers overlap each other, the overlapping part of the electrode layers comprising including a light emitting section made of organic EL elements;, the electrode layers including a first electrode layer which is one of electrode layers having a transparent property; and the organic EL device having
a dummy pattern placed in at least one of the same plane as the first electrode layer, such that the dummy pattern is electrically isolated from the first electrode layer and/or a dummy pattern placed in the same plane as the a second electrode layer, which is the other another electrode layer, such that the dummy pattern is electrically isolated from the second electrode layer.

3. (Amended) An The organic EL device according to claim 1, wherein the dummy pattern is being formed with the same material as the first electrode layer.

4. (Amended) An The organic EL device according to claim 2, wherein the dummy pattern placed in the same plane as the first electrode layer is being formed with the same material as the first electrode layers and the dummy pattern placed in the same plane as the second electrode layer is being formed with the same material as the second electrode layer.

5. (Twice Amended) An The organic EL device according to claim 1, wherein the dummy pattern is being formed within the light emitting area of the organic light emitting layer.

6. (Twice Amended) An The organic EL device according to claim 1, wherein the substrate has having a transparent property, and the first electrode layer is being an electrode layer formed on a substrate-side face of the organic light emitting layer.

7. (Amended) An The organic EL device according to claim 6, wherein the substrate is being made of soda glass, and the first electrode layer is being made of ITO (Indium Tin Oxide).

8. (Amended) An The organic EL device according to claim 6, wherein the second electrode layer formed on above a face of the organic light emitting layer opposite from the substrate has having a transparent property.

9. (Amended) A display panel having a layered structure, comprising:with
a substrate
electrode layers formed on the substrate;
a display element layer provided between the electrode layers formed on a above the substrate, the electrode layers including a first electrode layer which is one of electrode layers having a transparent property, the first electrode layer being formed in a pattern corresponding to a light emitting pattern, the pattern being displayed by applying a voltage between the electrode layers,; and
a display panel having within the display area a dummy pattern, within a display area, which is made of the same material as the first electrode layer and placed in the same plane as the first electrode layer so that the dummy pattern is electrically isolated from the first electrode layer.

10. (Amended) A display panel having a layered structure, comprising:with
a substrate;
electrode layers formed above the substrate;
a display element layer provided between the electrode layers formed on a above the substrate, each electrode layer being formed in a pattern where part of the electrode layers overlaps each other, the overlapping part of the electrode layers comprising including a display element section, a pattern being displayed by applying a voltage between the electrode layers, a display panel having the electrode layers including a first electrode layer which is one of the electrode layer having a transparent property; and having within the display area
a dummy pattern, within the display area, which is made of at least one of the same material as the first electrode layer and placed in the same plane as the first electrode layer in a state electrically isolated from the first electrode layer, and/or a dummy pattern which is made of the same material as the a second electrode layer and placed in the same plane as the second electrode layers which is the other another electrode layer, such that the dummy pattern is electrically isolated from the second electrode layer.

11. (Twice Amended) A The display panel according to claim 9, wherein the substrate has having a transparent property and the first electrode layer is being an electrode layer formed on a substrate-side face of a display element layer.

12. (Amended) A The display panel according to claim 11, wherein the substrate is being made of soda glassy and the first electrode layer is being made of ITO (Indium Tin Oxide).
